(19) United States
(12) Patent Application Publication
(10) Pub. No.: US 2026/0367316 A1
(43) Pub. Date: Nov. 19, 2026

(54) SEMICONDUCTOR DEVICE

(71) Applicant: Taiwan Semiconductor Manufacturing Company, Ltd., Hsinchu (TW)

(72) Inventors: Jung-Wei Cheng, Hsinchu City (TW); Chun-Chih Chuang, Taichung City (TW); Hsien-Pin Hu, Hsinchu County (TW)

(73) Assignee: Taiwan Semiconductor Manufacturing Company, Ltd., Hsinchu (TW)

(21) Appl. No.: 19/751,132

(22) Filed: Jul. 23, 2026

Related U.S. Application Data
(63) Continuation of application No. 18/669,560, filed on May 21, 2024.

(51) Int. Cl. G02B 6/122; G02B 6/13; H10W 90/00

(52) U.S. Cl. CPC G02B 6/122; G02B 6/13; H10W 90/00

(57) ABSTRACT

A semiconductor device includes an interconnect substrate, a photonic die having a first sidewall and a dam structure. The dam structure is disposed between the interconnect substrate and the photonic die, and the dam structure has an elongated shape along the first sidewall of the photonic die in a top view.

### CROSS-REFERENCE TO RELATED APPLICATION

This application is a continuation application of and claims the priority benefit of a prior application serial No. 18/669,560, filed on May 21, 2024. The entirety of the above-mentioned patent application is hereby incorporated by reference herein and made a part of this specification.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A - 1G are schematic cross-sectional views of various stages in a method of forming a semiconductor device according to some embodiments.

FIGS. 2A - 2D are partial schematic top views of various stages in a method of forming a semiconductor device according to some embodiments.

FIGS. 3A - 3E are schematic cross-sectional views of various stages in a method of forming a semiconductor device according to some embodiments.

FIGS. 4A - 4C are partial schematic top views of various stages in a method of forming a semiconductor device according to some embodiments.

FIG. 5A is a cross-sectional view of a semiconductor device according to some embodiments.

FIG. 5B is a partial schematic top view of a semiconductor device according to some embodiments.

FIG. 6 is a cross-sectional view of a semiconductor device according to some embodiments.

FIG. 7 is a partial schematic top view of a semiconductor device according to some embodiments.

FIG. 8A is a partial schematic top view of a semiconductor device according to some embodiments.

FIG. 8B is a cross-sectional view of a semiconductor device according to some embodiments.

FIG. 9 is a partial schematic top view of a semiconductor device according to some embodiments.

FIG. 10A is a cross-sectional view of a semiconductor device according to some embodiments.

FIG. 10B is a partial schematic top view of a semiconductor device according to some embodiments.

FIG. 11 illustrates a flowchart of a method of forming a semiconductor device according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in physical contact, and may also include embodiments in which additional features may be formed between the first and second features, such that the first and second features may not be in physical contact. In addition, the present disclosure may repeat reference numerals and/or letters in the various examples. This repetition is for the purpose of simplicity and clarity and does not in itself dictate a relationship between the embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

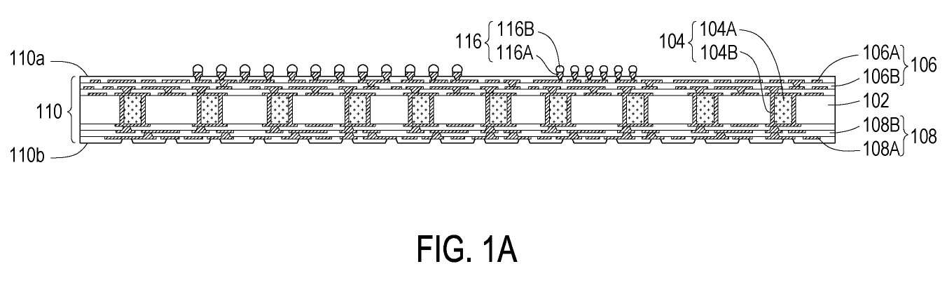

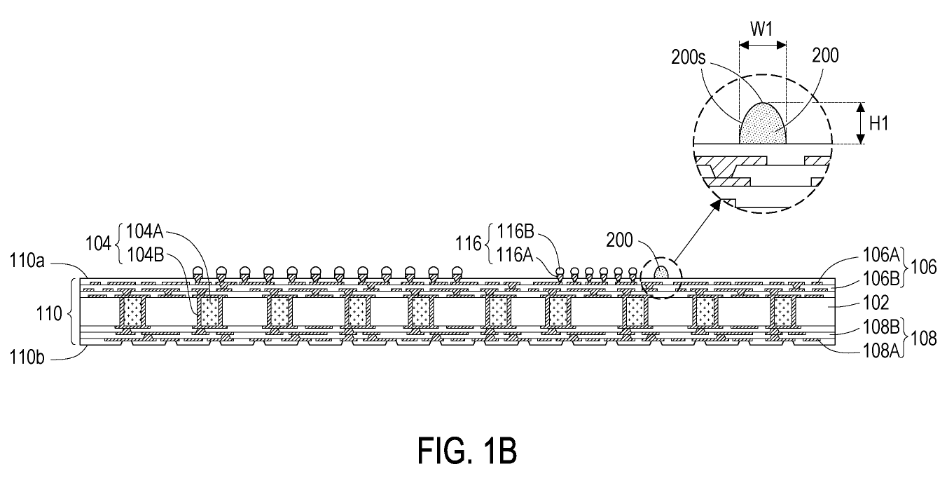

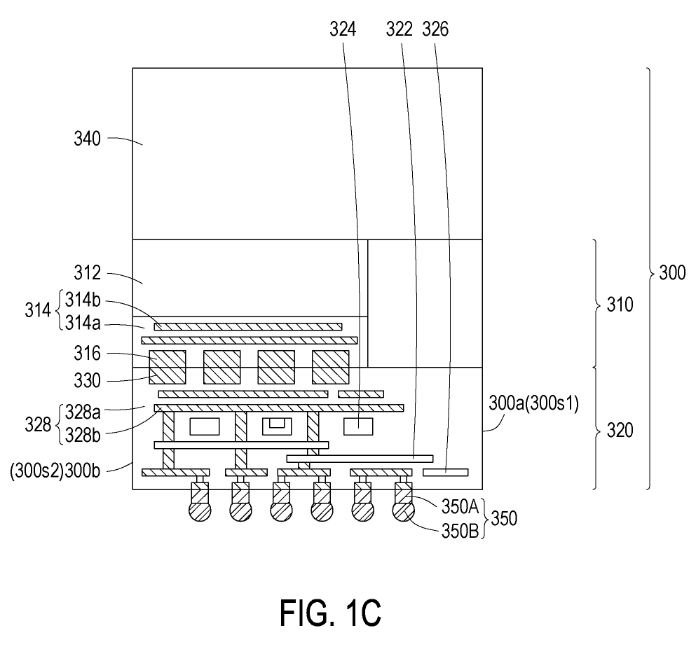

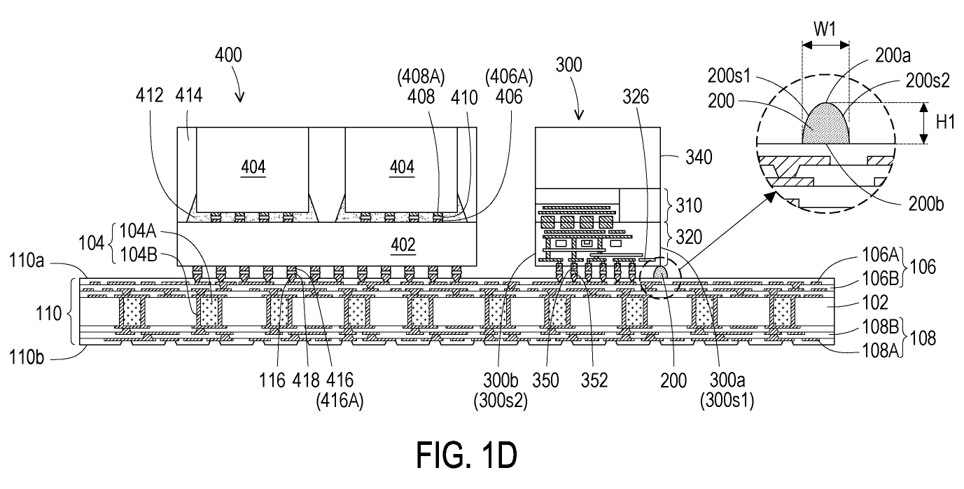

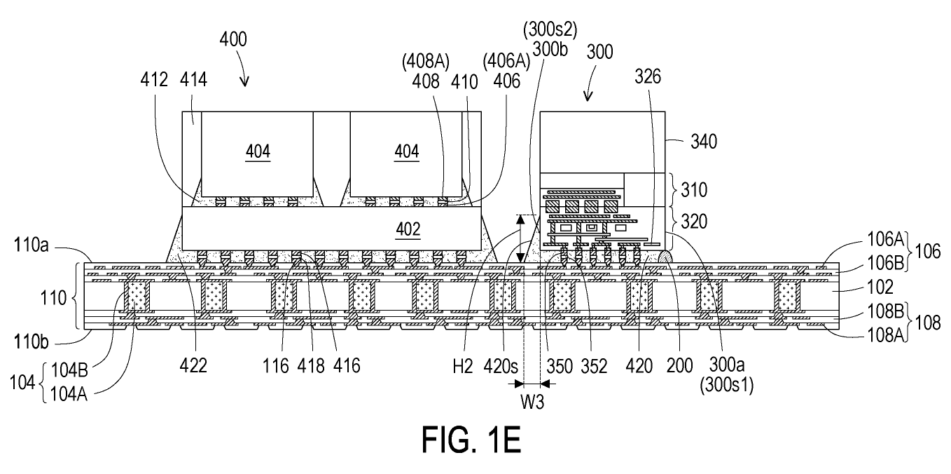

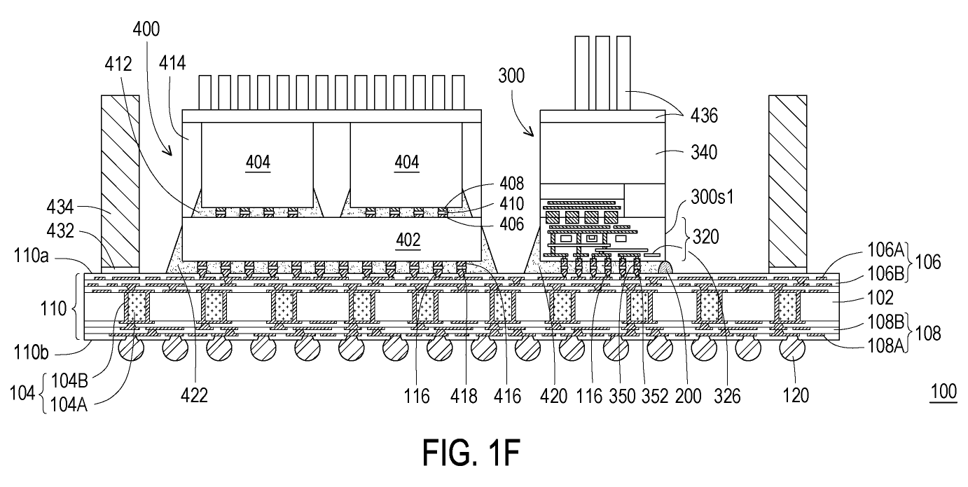

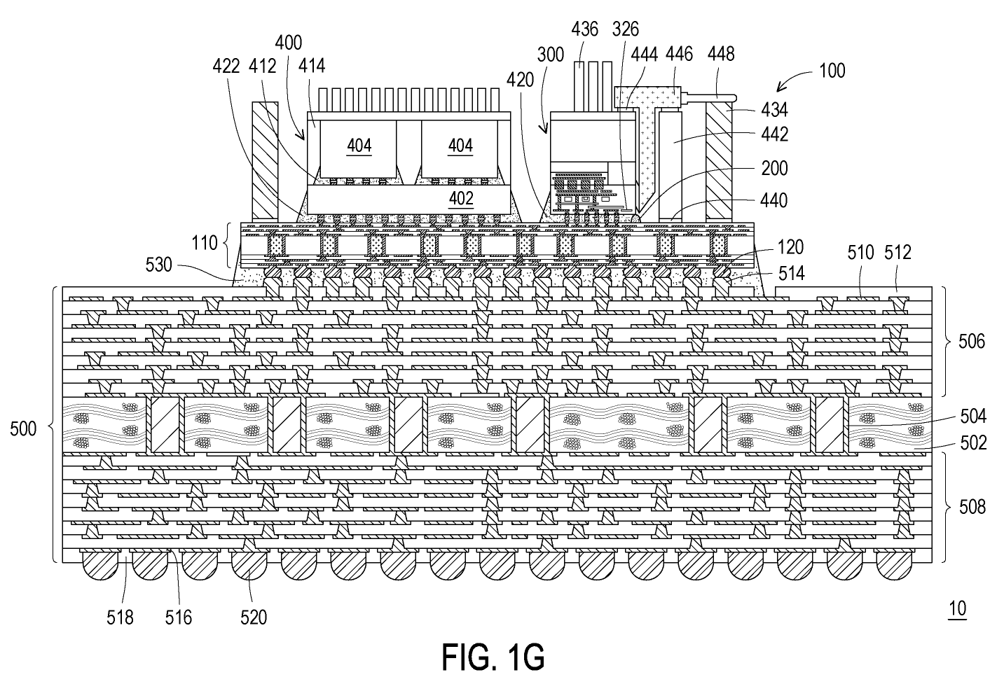

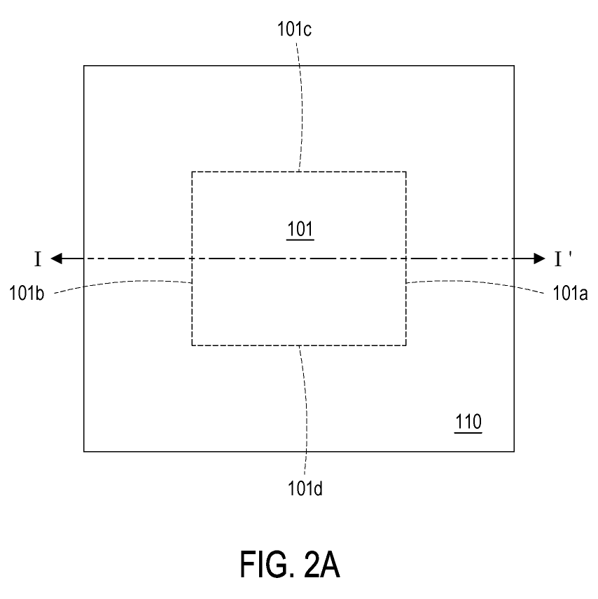

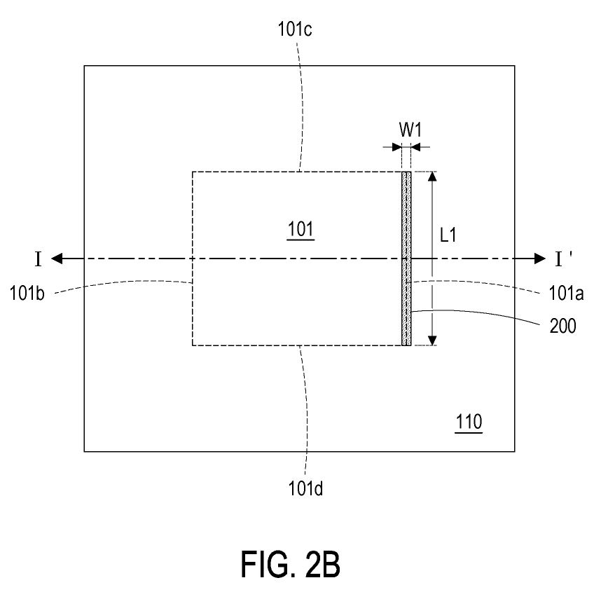

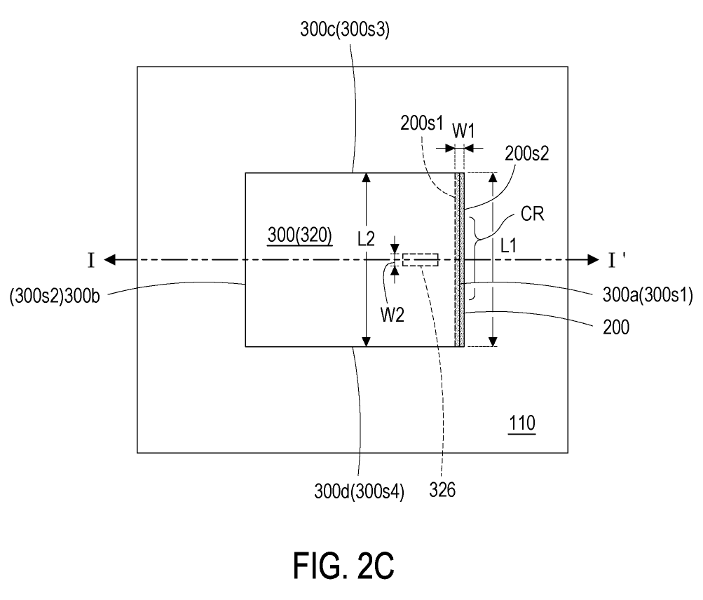

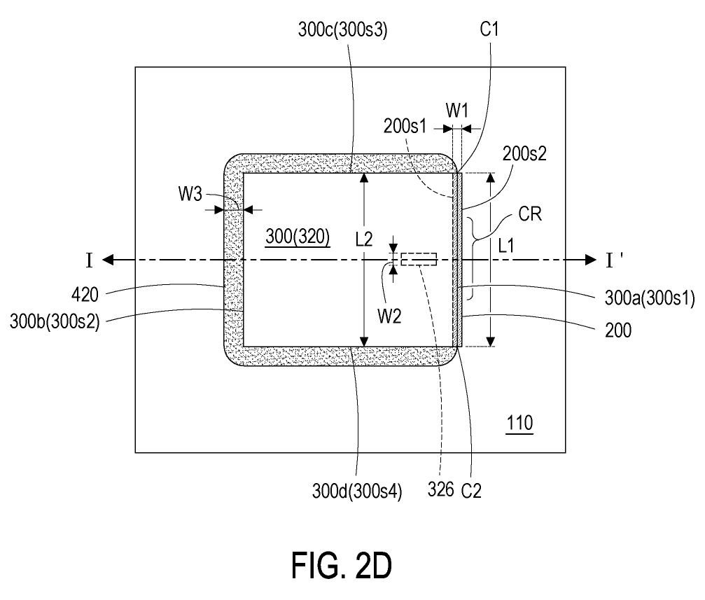

FIGS. 1A - 1G are schematic cross-sectional views of various stages in a method of forming a semiconductor device according to some embodiments. FIGS. 2A - 2D are partial schematic top views of various stages in a method of forming a semiconductor device according to some embodiments, and FIG. 1A to FIG. 1G may be cross-sectional views along an extending line I-I’ of FIGS. 2A - 2D. For clarity, some components of FIGS. 1A - 1G are omitted in FIGS. 2A - 2D.

Referring to FIGS. 1A and 2A, an interconnect substrate 110 is provided. The interconnect substrate 110 may be any suitable substrate includes a redistribution structure therein and/or thereon. In some embodiments, the interconnect substrate 110 includes a core material 102, a first redistribution structure 106 and a second redistribution structure 108. The interconnect substrate 110 has a first surface 110a (e.g., the surface facing upward in FIG. 1A) and a second surface 110b opposite to the first surface 110a. The interconnect substrate 110 may be also referred to as a package substrate.

The core material 102 may be formed of organic materials and/or inorganic materials. For example, the core material 102 includes one or more layers of glass fiber, resin, filler, pre-preg, epoxy, silica filler, Ajinomoto Build-up Film (ABF), polyimide, molding compound, other materials, and/or combinations thereof. In some embodiments, the core material 102 include two or more layers of material. In some embodiments, the core material 102 includes one or more passive components (not shown) embedded therein. The core material 102 may include other materials or components.

In some embodiments, conductive vias 104 extends through the core material 102. For example, the conductive vias 104 may include a fill material 104A and a conductive coating 104B surrounding the fill material 104A. In some embodiments, the fill material 104A is an insulating fill material, while the conductive coating 104B include conductive materials such as copper, a copper alloy, or other conductors. In some embodiments, the conductive vias 104 provide vertical electrical connections from one side of the core material 102 to the other side of the core material 102. For example, the conductive vias 104 are electrically connected to the first redistribution structure 106 and the second redistribution structure 108. In some embodiments, the conductive vias 104 is formed in the core material 102 using a drilling process, photolithography, a laser process, or another suitable technique to form an opening. Thereafter, the opening may be filled or plated with the conductive coating 104B, and further filled with the fill material 104A.

In some embodiments, the first redistribution structure 106 is formed on a first surface of the core material 102. The first redistribution structure 106 includes a plurality of conductive elements 106A and a plurality of dielectric layers 106B alternately stacked. In some embodiments, the second redistribution structure 108 is formed on a second surface of the core material 102. In a similar way, the second redistribution structure 108 includes a plurality of conductive elements 108A and a plurality of dielectric layers 108B alternately stacked. In some embodiments, the material of the dielectric layer 106B, 108B is polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layers 106B, 108B are formed by suitable fabrication techniques such as spin-on coating, chemical vapor deposition (CVD), plasma-enhanced chemical vapor deposition (PECVD) or the like. The disclosure is not limited thereto. In some embodiments, the material of the conductive elements 106A, 108A is made of conductive materials formed by electroplating or deposition, such as aluminum, titanium, copper, nickel, tungsten, and/or alloys thereof, which may be patterned using a photolithography and etching process. In some embodiments, the conductive elements 106A, 108A may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In some embodiments, a plurality of conductive connectors 116 are formed on and electrically connected to the first redistribution structure 106 to provide an external electrical connection to the circuitry and devices. For example, the conductive connectors 116 are formed at the front-side surface of the interconnect substrate 110. The conductive connectors 116 may be formed within a region 101 (shown in FIG. 2A) onto which a package component is to be bonded. The region 101 may include four sides 101a-d, the sides 101a, 101b are opposite to each other, and the sides 101c, 101d are opposite to each other. In some embodiments, the conductive connectors 116 are ball grid array (BGA) connectors, solder balls, metal pillars, controlled collapse chip connection (C4) bumps, micro bumps, electroless nickel-electroless palladium-immersion gold technique (ENEPIG) formed bumps, or the like.

The conductive connectors 116 may include underbump metallizations (UBMs) 116A and solder regions 116B over the UBMs 116A. The UBMs 116A may be conductive pillars, pads, or the like. In some embodiments, the UBMs 116A may be formed by forming a seed layer over the first redistribution structure 106. The seed layer may be a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the UBMs 116A. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, nickel, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the UBMs 116A.

In some embodiments, the UBMs 116A includes three layers of conductive materials, such as a layer of titanium, a layer of copper, and a layer of nickel. Other arrangements of materials and layers, such as an arrangement of chrome/chrome-copper alloy/copper/gold, an arrangement of titanium/titanium tungsten/copper, or an arrangement of copper/nickel/gold, may be utilized for the formation of the UBMs 116A. Any suitable materials or layers of material that may be used for the UBMs 116A are fully intended to be included within the scope of the current application.

The solder regions 116B may include a solder material and may be formed over the UBMs 116A by dipping, printing, plating, or the like. The solder material may include, for example, lead-based and lead-free solders, such as Pb-Sn compositions for lead-based solder; lead-free solders including InSb; tin, silver, and copper (SAC) compositions; and other eutectic materials that have a common melting point and form conductive solder connections in electrical applications. For lead-free solder, SAC solders of varying compositions may be used, such as SAC 105 (Sn 98.5%, Ag 1.0%, Cu 0.5%), SAC 305, and SAC 405, as examples. Lead-free solders may further include SnCu compounds as well, without the use of silver (Ag). Lead-free solders may also include tin and silver, Sn-Ag, without the use of copper. In some embodiments, a reflow process may be performed, giving the solder regions 116B a shape of a partial sphere in some embodiments. In alternative embodiments, the solder regions 116B may have other shapes, such as non-spherical shapes.

Referring to FIGS. 1B and 2B, a dam structure 200 is formed on the surface 110a of the interconnect substrate 110. In some embodiments, as shown in FIG. 2B, the dam structure 200 is formed along one side 101a of the region 101 onto which a package component is to be bonded. The dam structure 200 is separated from the conductive connectors 116 in the region 101. In some embodiments, the dam structure 200 has an elongated shape in a top view such as bar shape, line shape, rectangular shape, column shape and wall shape. The dam structure 200 may include a substantially constant width or a variable width. For example, a width W1 of the dam structure 200 is in a range of 10 μm to 200 μm. The width W1 is larger than a width of the conductive connector 116 and/or a width of the conductive connector 350 (shown in FIG. 1D), for example. As shown in FIG. 1B, the dam structure 200 may include a shape of a partial sphere in a cross-sectional view. For example, the dam structure 200 has a curved surface (e.g., curved sidewall) 200s. However, the disclosure is not limited thereto. The dam structure 200 may have any suitable shape such as non-spherical shape in a cross-sectional view. In some embodiments, the dam structure 200 may have a height H1 not smaller than a height of conductive connectors (e.g., conductive connectors 350 such as C4 bumps) of the package component to be bonded. For example, the height H1 of the dam structure 200 is in a range of 40 μm to 110 μm. In an embodiment, the height H1 of the dam structure 200 is higher than a height of the conductive connectors 116 of the interconnect substrate 110.

The dam structure 200 may include a glue material such as an UV glue, an adhesive material such as a thermal adhesive, a non-glue material such as solder resist, a conductive material such as metal or any suitable material. For example, the dam structure 200 includes epoxy-based material, silicone-based material, metal-based material, solder resist material, combinations thereof, or the like. The dam structure 200 may have a single layer structure or a multilayered structure. In some embodiments, the material of the dam structure 200 has elasticity. In some embodiments, the dam structure 200 includes an UV glue, and the formation of the dam structure 200 includes a dispensing process and a subsequent UV curing process. In an embodiment in which the dam structure 200 includes a thermal adhesive, the formation of the dam structure 200 includes a dispensing process and a subsequent thermal curing process. The thermal curing process may be performed under a temperature lower than 130 ℃. In an embodiment in which the dam structure 200 includes a non-glue material such as solder resist, the formation of the dam structure 200 includes a deposition process and a patterning process.

Referring to FIG. 1C, a package component 300 is provided. In some embodiments, the package component 300 is an optical integrated circuit die, such as an optical engine die. The package component 300 may include an electrical integrated circuit (EIC) 310 bonded to a photonic integrated circuit (PIC) (also referred to as a photonic die) 320. The EIC 310 may include a semiconductor substrate 312, active and/or passive electric devices on the active side of the semiconductor substrate 312, an interconnect structure 314 on the active side of the semiconductor substrate 312 and conductive connectors 316. The semiconductor substrate 312 may be a substrate of silicon, doped or undoped or a semiconductor-on-insulator (SOI) substrate. The semiconductor substrate 312 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 312 has a front-side surface and a backside surface. In some embodiments, active devices (e.g., transistors, diodes, etc.), capacitors, resistors, the like, or combinations thereof, are formed in and/or on the front-side surface of the substrate 312.

The interconnect structure 314 is formed over the front-side surface of the semiconductor substrate 312, and is used to electrically connect the devices (if any) of the semiconductor substrate 312. The interconnect structure 314 may include one or more dielectric layer(s) 314a and respective metallization layer(s) 314b in the dielectric layer(s) 314a. Acceptable dielectric materials for the dielectric layers 314a include low-k dielectric materials such as PSG, BSG, BPSG, USG, or the like. Acceptable dielectric materials for the dielectric layers 314a further include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The metallization layers 314b may include conductive vias and/or conductive lines to interconnect the devices (if any) of the semiconductor substrate 312. The metallization layers 314b may be formed of a conductive material, such as a metal, such as copper, cobalt, aluminum, gold, combinations thereof, or the like. The interconnect structure 314 may be formed by a damascene process, such as a single damascene process, a dual damascene process, or the like.

The conductive connectors 316 may be disposed on the interconnect structure 314. The conductive connectors 316 are conductive pads, for example. The PIC 320 may include optical devices, such as waveguides 322, modulators 324, or the like. The PIC 320 may also include an optical coupler, such as an edge coupler 326. In some embodiments, the edge coupler 326 includes a dielectric material (such as, silicon nitride, or the like) and is formed using physical vapor deposition (PVD), chemical vapor deposition (CVD), or the like. In alternative embodiments, the edge coupler 326 includes a semiconductor layer (such as, a silicon layer, or the like) and is formed from an SOI substrate. The edge coupler 326 may be disposed within the PIC 320 and at a first side 300a of the package component 300. In some embodiments, as shown in FIG. 2D, the edge coupler 326 is disposed corresponding to (e.g., aligned with) a central region CR of a sidewall 300s1 (or an edge) of the PIC 320. The sidewall 300s1 is also a sidewall of the package component 300, for example. As described below with greater detail, the edge coupler 326 provides optical coupling between the package component 300 and an optical fiber coupled to the package component 300. The PIC 320 may include an interconnect structure 328 aside the waveguides 322, the modulators 324 and/or the edge coupler 326. The interconnect structure 328 may include one or more dielectric layer(s) 328a and respective metallization layer(s) 328b in the dielectric layer(s) 328a. The interconnect structure 328 may be formed using similar materials and methods as the interconnect structure 314 described above, and the description is not repeated herein. The PIC 320 may include conductive connectors 330 bonded to the conductive connectors 316 of the EIC 310. The conductive connectors 330 are conductive pads, for example.

In some embodiments, the package component 300 further includes a carrier substrate 340, and the EIC 310 and the PIC 320 are disposed on the carrier substrate 340. The carrier substrate 340 may be also referred to as a supporting substrate. In some embodiments (not shown), a PIC wafer (including a plurality of PICs 320) is formed on a wafer, an EIC wafer (including a plurality of EICs 310) is bonded to the PIC wafer through, for example, a hybrid bonding, and then a carrier wafer (including a plurality of carrier substrates 340) is bonded to the EIC wafer through a bonding layer therebetween. The carrier wafer may be bonded to the wafer with the PIC wafer and the EIC wafer thereover through a wafer to wafer bonding. After that, the wafer may be entirely removed from the formed structure (e.g., from the backside of the formed structure), and the conductive connectors 350 may be formed on an outermost surface of the formed structure. In some embodiments, the conductive connectors 350 may be formed using similar materials and methods as the conductive connectors 116 described above with reference to FIG. 1A, and the description is not repeated herein. For example, the conductive connectors 350 include UBMs 350A and solder regions 350B over the UBMs 350A. Then, the formed structure including a plurality of die regions in which the EICs 310 and the PICs 320 are stacked is singulated, to form a plurality of package components 300. However, the disclosure is not limited thereto. The package component 300 may be formed by any suitable method and have any suitable configuration.

Referring to FIGS. 1D and 2C, the package component 300 is bonded to the interconnect substrate 110. As shown in FIG. 1D, the package component 300 is bonded to the interconnect substrate 110 using the conductive connectors 350 and the conductive connectors 116. The package component 300 may be placed on the interconnect substrate 110 using, e.g., a pick-and-place tool. After placing the package component 300 on the interconnect substrate 110, the solder regions 350B of the conductive connectors 350 are in physical contact with respective solder regions 116B of respective conductive connectors 116. Then, a reflow process may be performed on the conductive connectors 350 and 116. The reflow process may melt and merges the solder regions 350B and 116B into solder joints 352. The solder joints 352 electrically and mechanically couple the package component 300 to the interconnect substrate 110, for example.

In some embodiments, during the bonding process of the package component 300 and the interconnect substrate 110, the package component 300 also contacts with the dam structure 200. The dam structure 200 is physically separated from the conductive connectors 350 and the conductive connectors 116. The package component 300 is disposed in the region 101 of the interconnect substrate 110 and includes a first side 300a, a second side 300b opposite to the first side 300a, a third side 300c between the first and second sides 300a and 300b and the fourth side 300d opposite to the third side 300c, for example. The dam structure 200 is disposed corresponding to the edge coupler 326 of the package component 300. For example, the edge coupler 326 of the PIC 320 is disposed at the first side 300a of the package component 300, and the dam structure 200 is also disposed at the first side 300a of the package component 300. As shown in FIG. 2C, in the same horizontal direction (e.g., y direction), the length L1 of the dam structure 200 is not smaller than a width W2 of the edge coupler 326.

In some embodiments, the dam structure 200 extends beyond the first side 300a (e.g., sidewall 300s1) of the package component 300. That is, the dam structure 200 may partially overlap with the package component 300. For example, a first surface 200s1 (e.g., inner surface or inner sidewall) of the dam structure 200 is covered by the package component 300 while a second surface (e.g., outer surface or outer sidewall) 200s2 opposite to the first surface 200s1 of the dam structure 200 is not covered by the package component 300. In alternative embodiments, the dam structure 200 is entirely covered by the package component 300, that is, opposite first and second surfaces 200s1, 200s2 are inside the sidewall 300s1. In some embodiments, the dam structure 200 extends along the first side 300a of the package component 300. The dam structure 200 extends along the sidewall 300s1 of the PIC 320 and has a length L1 greater than 1/10 of a length L2 of the sidewall 300s1. The dam structure 200 may extend along the central portion CR of the sidewall 300s1 of the PIC 320. For example, the length L1 of the dam structure 200 is substantially equal to the length L2 of the sidewall 300s1 of the PIC 320. That is, the dam structure 200 may continuously extend along the sidewall 300s1 of the PIC 320. The dam structure 200 may contact the sidewall 300s1 of the PIC 320. The dam structure 200 may contact or not contact a corner C1 formed between the first and third sides 300a and 300c (e.g., sidewalls 300s1, 300s3) and/or a corner C2 formed between the first and fourth sides 300a and 300d (e.g., sidewalls 300s1, 300s4). In some embodiments, the first to fourth sides 300a-300d are also sides of the PIC 320 and the corners C1, C2 are also corners of the PIC 320. In alternative embodiments, the length L1 of the dam structure 200 is shorter than or longer than the length L2 of the first sidewall 300s1 of the PIC 320 as long as the length L1 of the dam structure 200 is not smaller than the width W2 of the edge coupler 326 of the PIC 320. In such embodiments, the dam structure 200 contacts or does not contact the corner C1 and/or the corner C2.

The dam structure 200 has a first surface (e.g., top surface) 200a and a second surface 200b opposite to the first surface 200a. In some embodiments, the first surface 200a of the dam structure 200 faces and is in physical contact with the package component 300 (e.g., surface of the PIC 320), and the second surface 200b of the dam structure 200 faces and is in physical contact with the surface 110a of the interconnect substrate 110 (e.g., dielectric layer 106B of the interconnect substrate 110). That is, the height H1 of the dam structure 200 is substantially equal to a total height of the conductive connector 350, the connector 116 and the joint 352 therebetween. In an embodiment in which the connector 116 is embedded in the interconnect substrate 110, the height H1 of the dam structure 200 is substantially equal to a total height of the conductive connector 350 and the joint 352 formed between the conductive connector 350 and the connector 116. The surface (e.g., sidewall) 200s1, 200s2 of the dam structure 200 is curved, respectively. The height H1 of the dam structure 200 of FIG. 1D is substantially the same as the height H1 of the dam structure 200 of FIG. 1B. In some embodiments, after contacting with the package component 300, the shape of the dam structure 200 is substantially retained. However, the disclosure is not limited thereto. In alternative embodiments, the shape of the dam structure 200 may be changed since the dam structure 200 is pressed against the package component 300. For example, a portion of the surface of the dam structure 200 contacting the package component 300 is flat and coplanar with the package component 300, and/or a height of the dam structure 200 is reduced.

In some embodiments, since the dam structure 200 is disposed between and overlapped the package component 300 and the interconnect substrate 110. The dam structure 200 may physically connect the package component 300 and the interconnect substrate 110, and the dam structure 200 may also provide stress buffer, support and/or adherence for the package component 300. In some embodiments, the dam structure 200 is also referred to as a stress buffer structure, a supporting structure and/or an adherence structure. Furthermore, in an embodiment in which a material of the dam structure 200 has a good thermal conductivity, the dam structure 200 may further provide heat dissipation to the formed package structure.

In some embodiments, another package component 400 may be also formed aside the package component 300 on the interconnect substrate 110. The package component 400 may include an interposer 402, a plurality of dies 404 on the interposer 402, an underfill 412 between the interposer 402 and the dies 404 and an encapsulant 414 encapsulating the dies 404. The dies 404 may be non-optical dies. For example, the die 404 is a logic die (e.g., central processing unit (CPU), graphics processing unit (GPU), system-on-a-chip (SoC), application processor (AP), microcontroller, etc.), a memory die (e.g., high bandwidth memory (HBM) die, dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, a switch die, or combinations thereof. In some embodiments, the dies 404 include a HBM die and a XPU die. The bonding between the dies 404 and the interposer 402 may be similar to that between the package component 300 and the interconnect substrate 110. For example, the interposer 402 and the dies 404 respectively include conductive connectors 406 and conductive connectors 408, and the conductive connectors 406, 408 include UBMs 406A, 408A and solder regions (not shown) over the UBMs 406A, 408A. The solder regions of the conductive connectors 408 may be in physical contact with respective solder regions of respective conductive connectors 406. Then, a reflow process may be performed on the conductive connectors 408 and 406. The reflow process may melt and merges the solder regions of the conductive connectors 408 and 406 into solder joints 410. The solder joints 410 electrically and mechanically couple the dies 404 to the interposer 402, for example. After the bonding, the underfill 412 is formed aside the conductive connectors 406, the conductive connectors 408 and the solder joints 410 therebetween, and in a gap between the interposer 402 and the dies 404, for example. The underfill 412 may be formed of an underfill material such as a molding compound, epoxy, or the like. Then, the encapsulant 414 may be formed over the interposer 402 to encapsulate the dies 404 and the underfill 412. The encapsulant 414 may be applied by compression molding, transfer molding, or the like. Then, the package component 400 may be bonded to the interconnect substrate 110. For example, the package component 400 includes conductive connectors 416, and the conductive connectors 416 include UBMs 416A and solder regions (not shown) over the UBMs 416A. The solder regions of the conductive connectors 416 may be in physical contact with respective solder regions 116B of respective conductive connectors 116. Then, by performing a reflow process, the solder regions of the conductive connectors 416 and the solder regions 116B of the conductive connectors 116 are melted and merged into solder joints 418. The solder joints 418 electrically and mechanically couple the package component 400 to the interconnect substrate 110, for example. In alternative embodiments, the package component 400 may have any other configurations and there may be more than one package components 400 over the interconnect substrate 110. In addition, the package component 400 may be bonded before or after bonding the package component 300 onto the interconnect substrate 110.

Referring to FIGS. 1E and 2D, an underfill 420 is formed around the conductive connectors 116 and 350. In some embodiments, the underfill 420 is formed around the conductive connectors 116, the conductive connectors 350 and the solder joints 352 therebetween, and in a gap between the interconnect substrate 110 and the package component 300. Similarly, the underfill 422 may be further formed around the conductive connectors 116, the conductive connectors 416 and the solder joints 418 therebetween, and in a gap between the interconnect substrate 110 and the package component 400. In some embodiments, the gap may have a height substantially the same as the height H1 of the dam structure 200. The underfill 420, 422 may reduce stress and protect the solder joints 352, 418. The underfill 420, 422 may be formed of an underfill material such as a molding compound, epoxy, or the like. The underfill 420 or 422 may be formed by a capillary flow process after the package component 300 or 400 is attached to the interconnect substrate 110, or may be formed by any suitable deposition method before the package component 300 or 400 is attached to the interconnect substrate 110. The underfill 420 may be formed before, simultaneously or after the formation of the underfill 422. In some embodiments, the formation of the underfill 420, 422 includes a dispensing process and a subsequent curing process. For example, the underfill 420, 422 is applied in liquid or semi-liquid form and then subsequently cured. The dam structure 200 is in physical contact with or separated from the underfill 420. In some embodiments, the dam structure 200 prevents the underfill 420 from physically contacting and extending along the sidewall 300s1 of the PIC 320. As shown in FIGS. 1E and 2D, the sidewall 300s2 is covered by the underfill 420, and the central region CR of the sidewall 300s1 is free of the underfill. In some embodiments, an entirety of the sidewall 300s1 is free of the underfill 420. Accordingly, the underfill 420 does not shield the edge coupler 326 of the PIC 320. In some embodiments, as shown in FIG. 2D, the underfill 420 continuously contacts and extends along the sidewalls 300s2, 300s3, 300s4 at the sides 300b, 300c, 300d of the PIC 320 with a height H2. In some embodiments, as shown in FIG. 1E, the underfill 420 may have an inclined sidewall 420s at the side 300b of the package component 300. For example, as shown in FIGS. 1E and 2D, the underfill 420 has a width W3 extending beyond the sidewalls 300s2-300s4 of the package component 300. However, the disclosure is not limited thereto. In alternative embodiments, the underfill 420 further extends along a portion of the side 300a without shielding the edge coupler 326 of the package component 300.

In some embodiments, a first portion (i.e., inner portion) of the dam structure 200 facing the conductive connectors 350 of the package component 300 (also the conductive connectors 116 of the interconnect substrate 110) is in physical contact with the underfill 420 while a second portion (i.e., outer portion) opposite to the first portion of the dam structure 200 away from the conductive connectors 350 of the package component 300 (also the conductive connectors 116 of the interconnect substrate 110) is not in physical contact with the underfill 420. The first portion of the dam structure 200 is the surface (e.g., sidewall) 200s1, and the second portion of the dam structure 200 is the surface (e.g., sidewall) 200s2, for example. In alternative embodiments, an entirety of the dam structure 200 is not in physical contact with the underfill 420. For example, the dam structure 200 is physically separated from the underfill 420.

Referring to FIG. 1F, after the underfill 420 is formed, a plurality of conductive connectors 120 are formed on the interconnect substrate 110, to form a package structure 100. In some embodiments, the formed structure is flipped over and is attached to a carrier wafer. The carrier wafer is used as a platform or a support for a packaging process described below. In some embodiments, the carrier wafer includes a semiconductor material (such as silicon, or the like), a dielectric material (such as glass, a ceramic material, quartz, or the like), the like, or combinations thereof. Subsequently, the conductive connectors 120 are formed on the second surface 110b (e.g., the backside) of the interconnect substrate 110 to electrically connect to the second redistribution structure 108. In the illustrated embodiment, the conductive connectors 120 include ball grid array (BGA) connectors or the like.

Then, the formed structure is mounted onto a frame (not specifically illustrated), and de-bonded from the carrier wafer. The formed structure including the interconnect substrate 110 and the package components 300, 400 is de-bonded from the carrier wafer, and a package structure 100 is formed. In some embodiments, some components providing supports and/or heat dissipation may be further formed over the interconnect substrate 110. For example, a warpage control structure 434 is attached to the interconnect substrate 110. The warpage control structure 434 may be attached to the interconnect substrate 110 by an adhesive 432, such that the adhesive 432 is interposed between the warpage control structure 434 and the interconnect substrate 110. The adhesive 432 may be any suitable adhesive, epoxy, or the like. The warpage control structure 434 may be a ring and surround the package components 300, 400 and the dam structure 200. The warpage control structure 434 may include a metal, a metal alloy, a dielectric material, a semiconductor material, or the like. After forming the warpage control structure 434, heat dissipation components 436 may be formed over the package components 300 and 400, for example. However, the disclosure is not limited thereto. In alternative embodiments, the above components may be omitted and have any suitable configuration and/or arrangement.

Referring to FIG. 1G, the package structure 100 is then bonded to an interconnect substrate 500 through the conductive connectors 120, to form a semiconductor device 10. The interconnect substrate 500 includes a substrate core 502, which may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, or the like, may also be used. Additionally, the substrate core 502 may be a SOI substrate. Generally, an SOI substrate includes a layer of a semiconductor material such as epitaxial silicon, germanium, silicon germanium, SOI, SGOI, or combinations thereof. In another embodiment, the substrate core 502 is an insulating core such as a fiberglass reinforced resin core. One example core material is fiberglass resin such as FR4. Alternatives for the core material include bismaleimide-triazine (BT) resin, or alternatively, other printed circuit board (PCB) materials or films.

In some embodiments, the substrate core 502 includes active and passive devices (not separately illustrated). Devices such as transistors, capacitors, resistors, combinations thereof, and the like may be used to generate the structural and functional requirements of the design for the system. The devices may be formed using any suitable methods. In some embodiments, the substrate core 502 is substantially free of active and passive devices. In some embodiments, the substrate core 502 further includes conductive vias 504, which may be also referred to as TSVs.

The interconnect substrate 500 may also include a redistribution structure. In some embodiments, the redistribution structure is formed of alternating layers of dielectric material (e.g., low-k dielectric material) and conductive material (e.g., copper) with vias interconnecting the layers of conductive material, and is formed through any suitable process (such as deposition, damascene, or the like). In other embodiments, the redistribution structure is formed of alternating layers of dielectric material (e.g., build up films such as Ajinomoto build-up film (ABF) or other laminates) and conductive material (e.g., copper) with vias interconnecting the layers of conductive material, and is formed through any suitable process (such as lamination, plating, or the like).

In the illustrated embodiment, the interconnect substrate 500 includes redistribution structures 506 and 508 formed on opposing surfaces of the substrate core 502, such that the substrate core 502 is interposed between the redistribution structure 506 and the redistribution structure 508. The conductive vias 504 electrically couple the redistribution structure 506 to the redistribution structure 508. In alternative embodiments, the redistribution structure 506 or the redistribution structure 508 is omitted.

In some embodiments, bond pads 510 and a solder resist layer 512 are formed on the redistribution structure 506, with the bond pads 510 being exposed by openings formed in the solder resist layer 512. The bond pads 510 may be a part of the redistribution structure 506 and may be formed together with other conductive features of the redistribution structure 506. The solder resist layer 512 may include a suitable insulating material (such as a dielectric material, a polymer material, or the like) and may be formed using any suitable deposition methods.

In some embodiments, conductive connectors 514 extend through the opening in the solder resist layer 512 and contact the bond pads 510. The conductive connectors 514 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In the illustrated embodiment, the conductive connectors 514 includes solder balls.

In some embodiments, bond pads 516 and a solder resist layer 518 are formed on the redistribution structure 508. The bond pads 516 may be a part of the redistribution structure 508 and may be formed together with other conductive features of the redistribution structure 508. The solder resist layer 518 may include a suitable insulating material (such as a dielectric material, a polymer material, or the like) and may be formed using any suitable deposition methods. Conductive connectors 520 extend through the opening in the solder resist layer 518 and contact the bond pads 516, for example.

In some embodiments, conductive connectors 520 extend through the openings in the solder resist layer 518 and contact the bond pads 516. The conductive connectors 520 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 520 may be formed using similar materials and methods as the conductive connectors 116 described above with reference to FIG. 1A, and the description is not repeated herein. In the illustrated embodiment, the conductive connectors 520 comprise solder balls.

In some embodiments, the package structure 100 is placed on the surface 500a of the interconnect substrate 500 using, e.g., a pick-and-place tool. After placing the package structure 100 on the interconnect substrate 500, the conductive connectors 120 are in physical contact with respective conductive connectors 514 including solder regions (not shown), such that the conductive connectors 120 are in physical contact with the solder regions of the respective conductive connectors 514. In some embodiments, after placing the package structure 100 on the interconnect substrate 500, a reflow process is performed to mechanically and electrically attach the package structure 100 to the interconnect substrate 500. The reflow process melts and merges the conductive connectors 120 and respective solder materials of the conductive connectors 514 into solder joints (not shown). The solder joints electrically and mechanically couple the package structure 100 to the interconnect substrate 500.

In some embodiments, an underfill 530 is formed around the conductive connectors 120 and the conductive connectors 514, and in a gap between the package structure 100 and the interconnect substrate 500. The underfill 530 may reduce stress and protect the solder joints formed between the conductive connectors 120 and the conductive connectors 514. The underfill 530 may be formed of an underfill material such as a molding compound, epoxy, or the like. The underfill 530 may be formed by a capillary flow process after the package structure 100 is attached to the interconnect substrate 500, or may be formed by a suitable deposition method before the package structure 100 are attached to the interconnect substrate 500. The underfill 530 may be applied in liquid or semi-liquid form and then subsequently cured. In some embodiments, the underfill 530 extends along the sidewalls of the package structure 100. For example, the underfill 530 extends along the sidewalls of the interconnect substrate 110.

In some embodiments, some components providing optical pathway may be further formed over the package structure 100 after the package structure 100 is bonded to the interconnect substrate 500. For example, a fiber array unit 446 is attached to the package component 300. The fiber array unit 446 provides an interface between the edge coupler 326 of the PIC 320 and an optical fiber 448 that is attached to the fiber array unit 446. In some embodiments, before attaching the fiber array unit 446 to the package component 300, a support structure 442 is attached to the package structure 100 using an adhesive 440. The support structure 442 may comprise a semiconductor material (such as, for example, silicon), a dielectric material, a combination thereof, or the like. The adhesive 440 may be formed using similar materials and methods as the adhesive 432. The fiber array unit 446 may be also attached to the sidewall 300s1 of the package component 300 using an optical glue 444, such that the optical glue 444 is in physical contact with and is interposed between the package component 300 and the fiber array unit 446. However, the disclosure is not limited thereto. In alternative embodiments, the above components may be omitted and have any suitable configuration and/or arrangement.

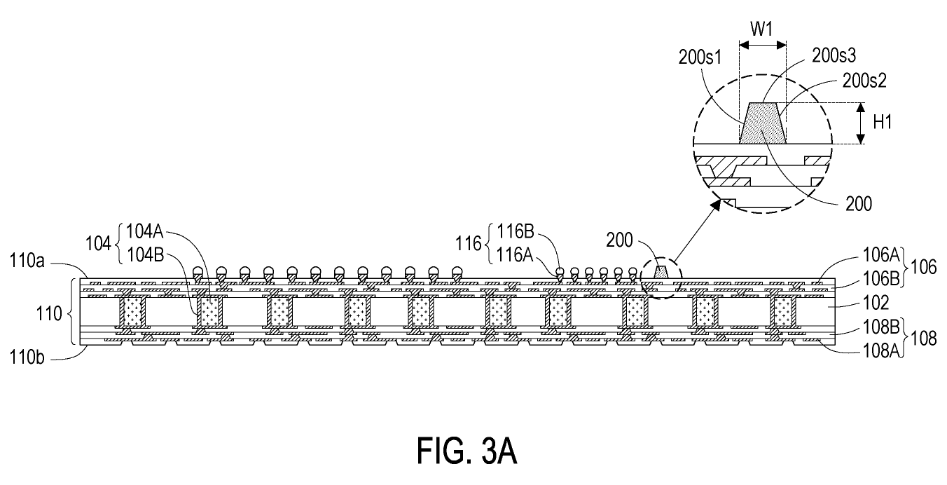

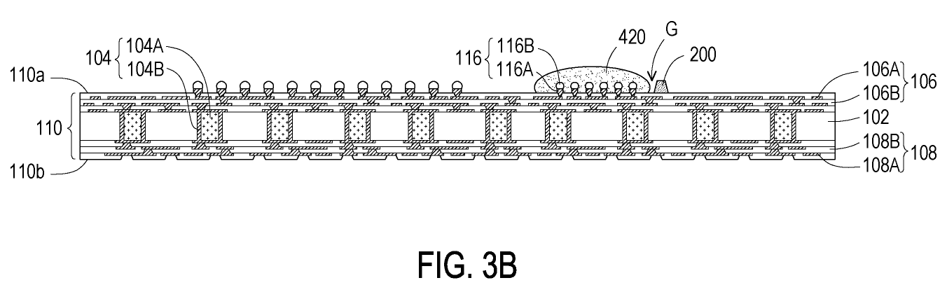

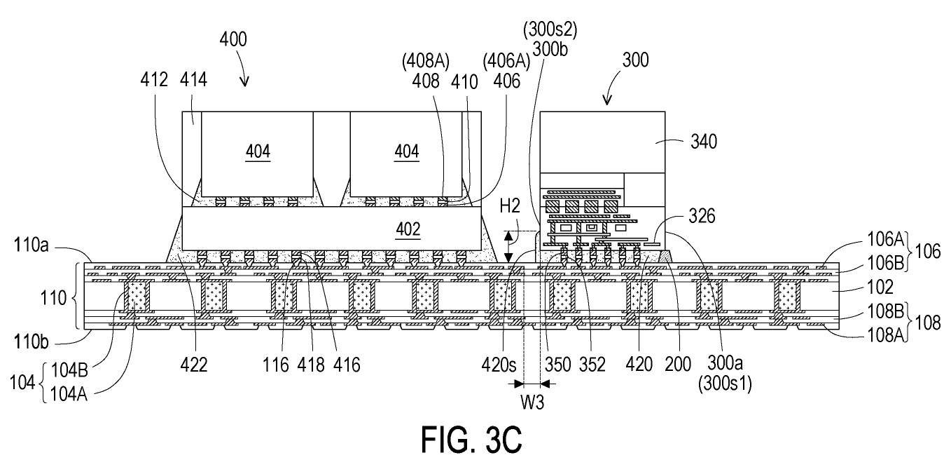

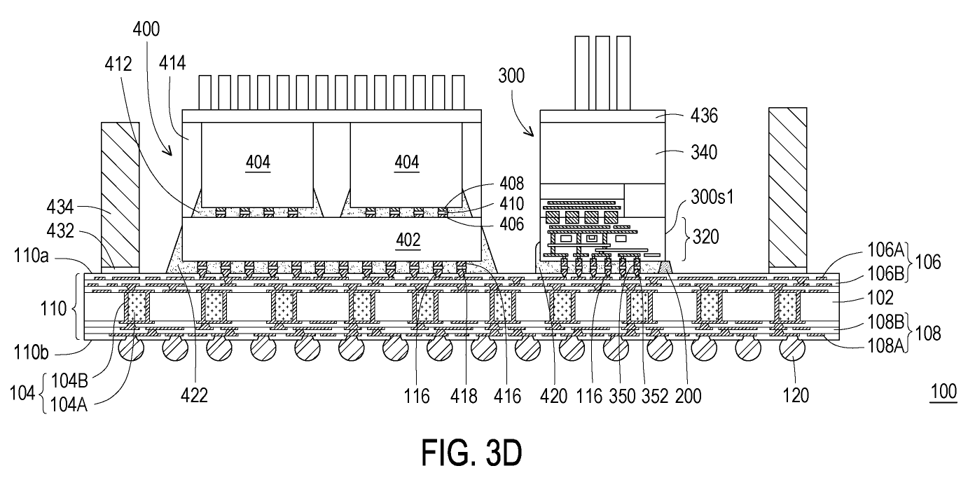

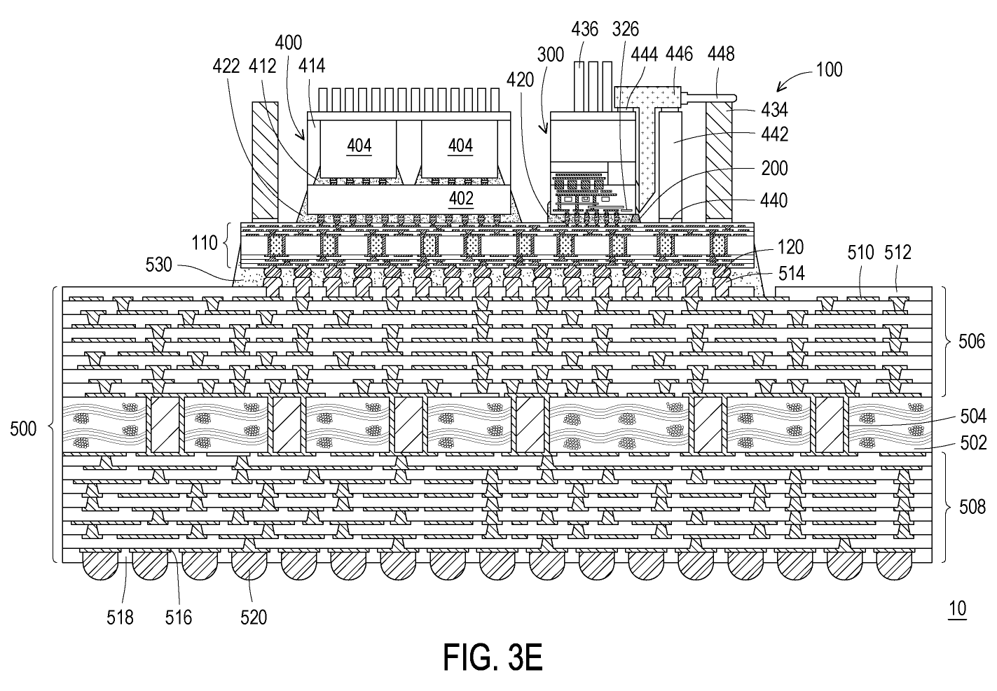

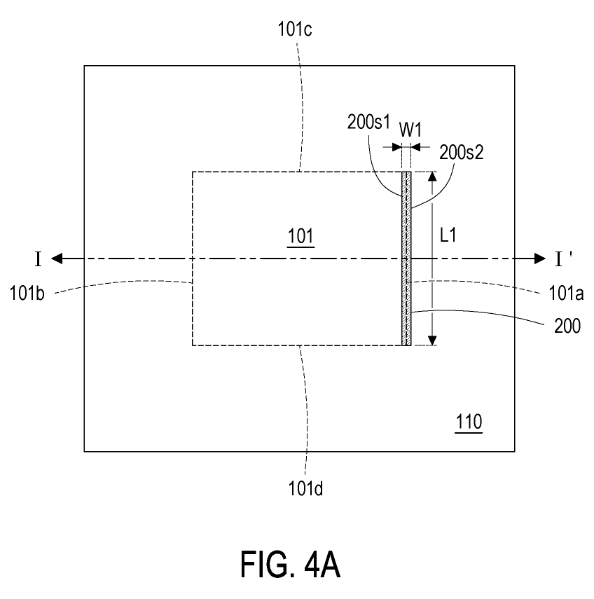

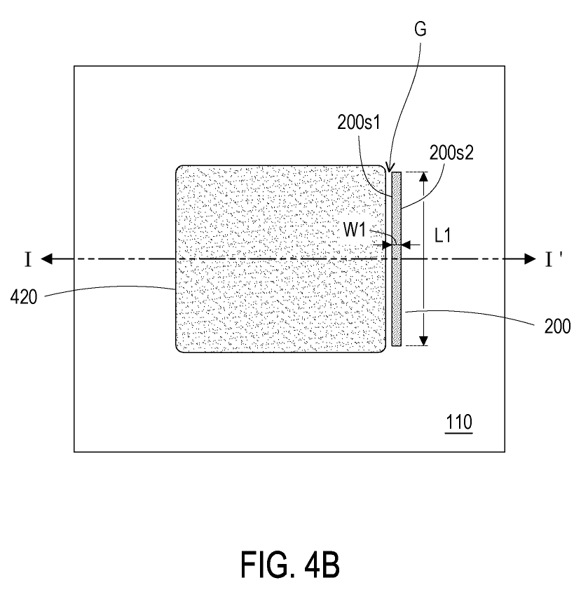

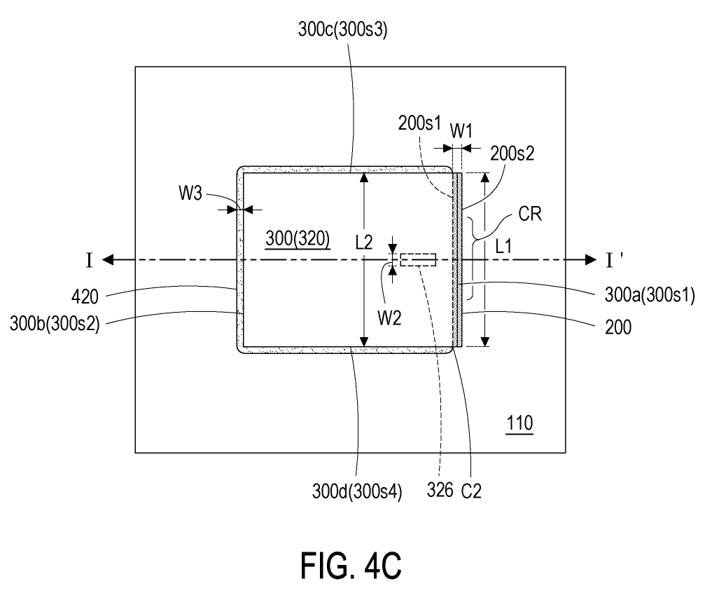

In some embodiments, the dam structure 200 is formed before the underfill 420. However, the disclosure is not limited thereto. FIGS. 3A - 3E are schematic cross-sectional views of various stages in a method of forming a semiconductor device according to some embodiments. FIGS. 4A - 4C are partial schematic top views of various stages in a method of forming a semiconductor device according to some embodiments, and FIGS. 3A - 3E may be cross-sectional views along an extending line I-I’ of FIGS. 4A - 4C. For clarity, some components of FIGS. 3A - 3E are omitted in FIGS. 4A - 4C.

Referring to FIGS. 3A and 4A, an interconnect substrate 110 with a dam structure 200 thereon is provided. In some embodiments, a material of the dam structure 200 includes solder resist or the like. The solder resist may include a suitable insulating material (such as a dielectric material, a polymer material, or the like). The dam structure 200 may be formed by a lithography process. In some embodiments, the dam structure 200 is bar-shaped, line-shaped, rectangular-shaped, column-shaped, wall-shaped or has any suitable shape. The dam structure 200 may include a shape of a rectangle, a trapezoid or the like in a cross-sectional view. For example, the dam structure 200 has a slanted sidewall or a substantially vertical sidewall 200s1, 200s2 and/or a substantially flat top surface 200s3. In some embodiments, the dam structure 200 may have a height H1 not smaller than a height of conductive connectors (e.g., conductive connectors 350 such as C4 bumps) of the package component to be bonded. For example, the height H1 of the dam structure 200 is in a range of 40 μm to 110 μm. The dam structure 200 may be formed during the manufacture of the interconnect substrate 110. In such embodiments, the dam structure 200 is a part of the interconnect substrate 110 and formed with the interconnect substrate 110 by a substrate supplier. For example, a solder resist layer is formed over a dielectric layer 106B of an first redistribution structure 106 by a suitable deposition process, and the solder resist layer is patterned by using a lithography process to form the dam structure 200. As shown in FIG. 4A, the dam structure 200 may be formed along one side 101a of a region 101 of the interconnect substrate 110 onto which a package component 300 is to be bonded. In alternative embodiments, the dam structure 200 may be formed using similar materials and methods as the dam structure 200 described above with reference to FIG. 1B, and the description is not repeated herein.

Referring to FIGS. 3B and 4B, an underfill 420 is formed over the interconnect substrate 110. For example, the underfill 420 is formed in the region 101 along the sides 101b-101d. In some embodiments, the underfill 420 is formed to be separated from the dam structure 200. That is, a gap G is formed between the underfill 420 and the dam structure 200. In some embodiments, the underfill 420 is a Non-Conductive Paste (NCP), a Non-Conductive Film (NCF) or the like and formed by a dispensing process or any suitable process.

Referring to FIGS. 3C and 4C, after formation of the underfill 420, the package component 300 is bonded to the interconnect substrate 110. The package component 300 may be attached onto the region 101 of the interconnect substrate 110 using, e.g., a thermal compression bonding (TCB) tool. After attaching the package component 300 on the interconnect substrate 110, the solder regions 350B of the conductive connectors 350 are in physical contact with respective solder regions 116B of respective conductive connectors 116. In some embodiments, during the bonding process of the package component 300 and the interconnect substrate 110, the package component 300 also contacts with the dam structure 200 as shown in FIGS. 3C and 4C. That is, the gap G between the underfill 420 and the dam structure 200 is not present, for example. However, the disclosure is not limited thereto. In alternative embodiments, the gap G between the underfill 420 and the dam structure 200 may be retained or be decreased. In some embodiments, as shown in FIG. 3C, the underfill 420 may have a substantially vertical sidewall 420s at the side 300b of the package component 300 due to the adhesive property. For example, compared to the sidewall 420s of the underfill 420 as shown in FIG. 1E, the sidewall 420s of the underfill 420 is more vertical. Furthermore, as shown in FIG. 3C, the amount of the underfill 420 extending onto the side 300b of the package component 300 may be less than the amount of the underfill 420 extending onto the side 300b of the package component 300 as shown in FIG. 1E. For example, a height H2 of the underfill 420 onto the sidewall 300s2 of the package component 300 shown in FIG. 3C may be smaller than a height H2 of the underfill 420 onto the sidewall 300s2 of the package component 300 shown in FIG. 1E. A width W3 of the underfill 420 extending beyond the sidewalls 300s2-300s4 of the package component 300 shown in FIGS. 3C and 4C may be less than the width W3 of the underfill 420 extending beyond the sidewalls 300s2-300s4 of the package component 300 shown in FIGS. 1E and 2D. However, the disclosure is not limited thereto. The height H2 of the underfill 420 of FIG. 3C may be larger than or substantially equal to that of the underfill 420 of FIG. 1E and/or the width W3 of the underfill 420 of FIG. 3C may be larger than or substantially equal to that of the underfill 420 of FIG. 1E.

Similar to the embodiments with reference to FIGS. 1D - 1G, another package component 400 may be also formed aside the package component 300 on the interconnect substrate 110, and an underfill 422 is formed aside the package component 400. The package component 400 may be bonded before or after bonding the package component 300 onto the interconnect substrate 110. The underfill 422 may be formed by using the material and process the same as or similar to the underfill 420 of FIG. 3B before bonding the package component 400. In alternative embodiments, the underfill 422 may be formed by using the material and process the same as or similar to the underfill 422 of FIG. 1E after bonding the package component 400. After that, conductive connectors 120 are formed on the interconnect substrate 110, to form a package structure 100 of FIG. 3D. Then, the package structure 100 of FIG. 3D may be further bonded to an interconnect substrate 500, to form a semiconductor device 10 of FIG. 3E. In some embodiments, some components 432-436 and 440-448 may be formed over the interconnect substrate 110 or the interconnect substrate 500.

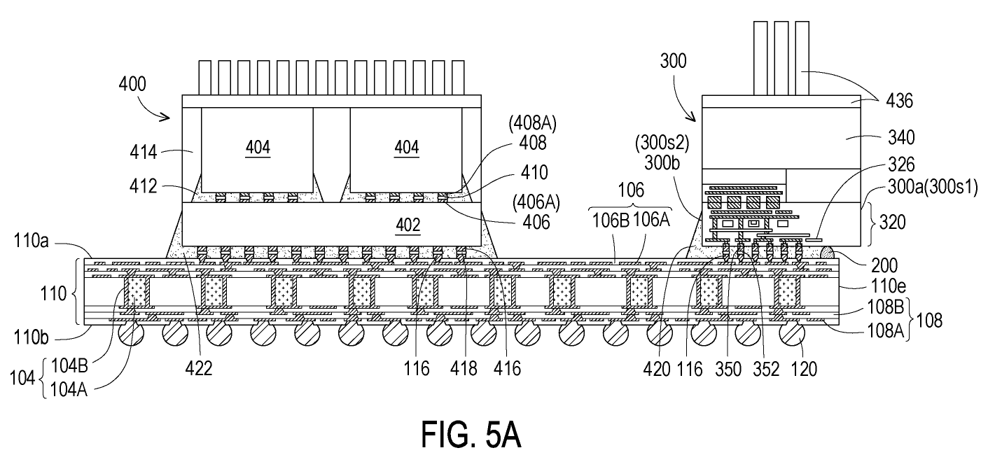

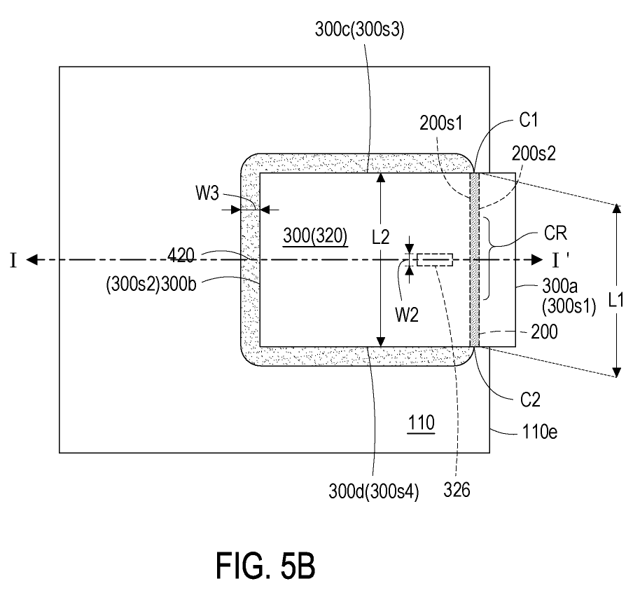

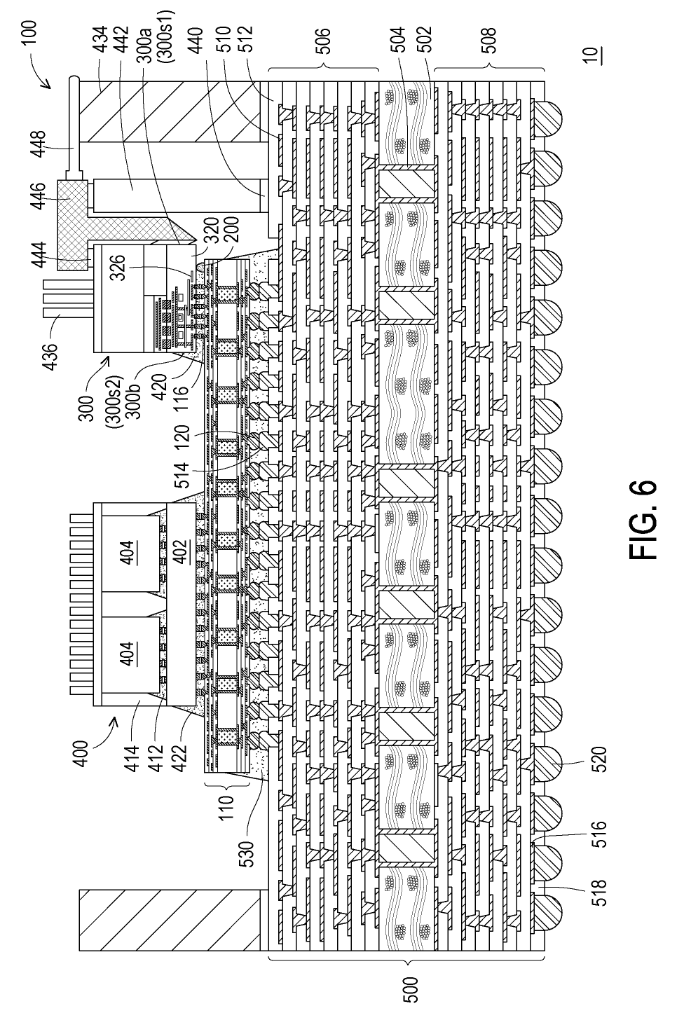

FIG. 5A is a schematic cross-sectional view of a package structure according to some embodiments, and FIG. 5B is a partial top view of a package structure according to some embodiments. FIG. 6 is a schematic cross-sectional view of a semiconductor device including the package structure of FIG. 5A. The package structure of FIGS. 5A and 5B and the semiconductor device of FIG. 6 are similar to the package structure of FIGS. 1F and 2D and the semiconductor device of FIG. FIG. 1G, and the difference lies in the dam structure 200 is formed at (e.g., immediately adjacent to) an edge 110e of the interconnect substrate 110, and an edge (e.g., sidewall 300s1) of the package component 300 (e.g., PIC 320) overhangs the edge 110e of the interconnect substrate 110.

In some embodiments, as shown in FIGS. 5A and 5B, the dam structure 200 is formed at (e.g., immediately adjacent to) the edge 110e of the interconnect substrate 110. The dam structure 200 is physically separated from the conductive connectors 160 and disposed between the conductive connectors 116 and the edge 110e of the interconnect substrate 110. The dam structure 200 may be formed during or after the formation of the interconnect substrate 110. The dam structure 200 may be formed using similar materials and methods as the dam structure 200 described above with reference to FIGS. 1B or 3A, and the description is not repeated herein.

In some embodiments, the package component 300 (e.g., PIC 320) is disposed overhanging the edge 110e of the interconnect substrate 110. For example, the side 300a (e.g., sidewall 300s1) of the package component 300 (e.g., PIC 320) is disposed outside the edge 110e of the interconnect substrate 110. The dam structure 200 may be entirely covered by the package component 300. That is, the dam structure 200 may entirely overlap with the package component 300. For example, opposite sidewalls (e.g., outer and inner sidewalls) 200s1, 200s2 of the dam structure 200 are covered by the package component 300. In some embodiments, the dam structure 200 extends along the sidewall 300s1 of the PIC 320. For example, the length L1 of the dam structure 200 is substantially equal to the length L2 of the sidewall 300s1 of the PIC 320. That is, the dam structure 200 may continuously extend along the sidewall 300s1 of the PIC 320. However, the disclosure is not limited thereto. The length L1 of the dam structure 200 may be shorter than or longer than the length L2 of the sidewall 300s1 of the PIC 320.

In some embodiments, the underfill 420 is formed along sides 101b-101d of the region 101 of the interconnect substrate 110 onto which a package component 300 is to be bonded. The underfill 420 may be formed before or after bonding the package structure 300 onto the interconnect substrate 110. The underfill 420 may be formed using similar material and method as the underfill 420 described above with reference to FIGS. 1E or 3B, and the description is not repeated herein. The dam structure 200 is in physical contact with or separated from the underfill 420. In some embodiments, the dam structure 200 prevents the underfill 420 from physically contacting and extending along the sidewall 300s1 of the PIC 320. Accordingly, the underfill 420 does not shield the edge coupler 326 of the package component 300.

In some embodiments, another package component 400 may be also formed aside the package component 300 on the interconnect substrate 110, and an underfill 422 is formed aside the package component 400. The package component 400 may be bonded before or after bonding the package component 300 onto the interconnect substrate 110. The underfill 422 may be formed by using the underfill 422 of FIG. 1E after bonding the package component 400 or the underfill 422 of FIG. 3D before bonding the package component 400. After that, the conductive connectors 120 are formed, to form a package structure 100 of FIG. 5A. Then, the package structure 100 of FIG. 5A may be further bonded to an interconnect substrate 500, to form a semiconductor device 10 of FIG. 6. In some embodiments, some components 432-436 and 440-448 may be formed over the interconnect substrate 110 or the interconnect substrate 500. In some embodiments, as shown in FIG. 6, the warpage control structure 434 and the support structure 442 may be disposed on the interconnect substrate 500 such as the solder resist layer 512 through the adhesives 432 and 440.

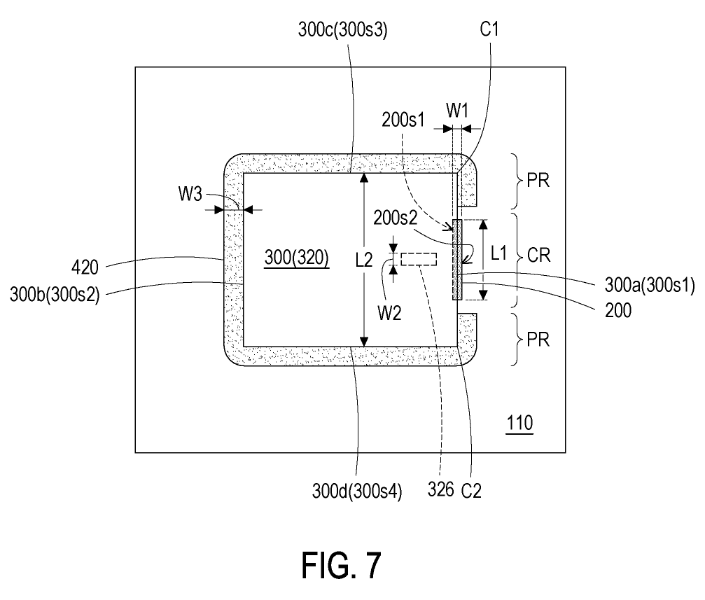

In above embodiments, the dam structure 200 is substantially formed along an entirety of the sidewall 300s1 of the PIC 320. For example, the length L1 of the dam structure 200 is substantially equal to the length L2 of the sidewall 300s1 of the PIC 320. However, the disclosure is not limited thereto. In some embodiments, as shown in FIG. 7, the edge coupler 326 is disposed corresponding to the central region CR of the sidewall 300s1 of the PIC 320, and the dam structure 200 is also disposed corresponding to the central region CR of the sidewall 300s1 of the PIC 320 without extending along the entire side 300a. That is, the length L1 of the dam structure 200 is smaller than the entire length L2 of the sidewall 300s1 of the PIC 320. In addition, the length of the dam structure 200 is larger than a width W2 of the edge coupler 326, such that the dam structure 200 may prevent the underfill 420 from physically contacting and extending along the central region CR of the sidewall 300s1 of the PIC 320. In some embodiments, the underfill 420 may be further formed along a peripheral region PR of the sidewall 300s1 of the PIC 320. For example, the underfill 420 continuously extends onto the sidewalls 300s2, 300s3, 300s4 and the peripheral regions PR of the sidewall 300s1 of the PIC 320 without covering the dam structure 200. In such embodiments, the corner C1 between the sidewalls 300s1 and 300s3 and/or the corner C2 between the sidewalls 300s1 and 300s4 are encapsulated (e.g., surround) and protected by the underfill 420. In alternative embodiments, the underfill 420 may extend only at the sidewalls 300s2, 300s3, 300s4.

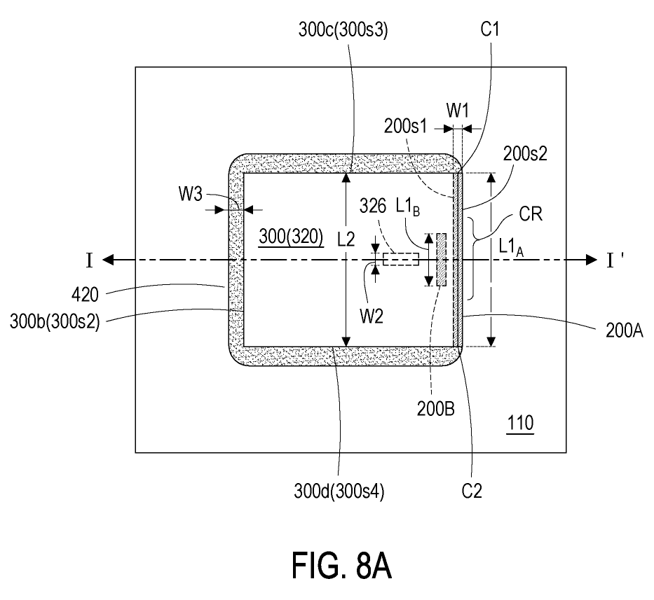

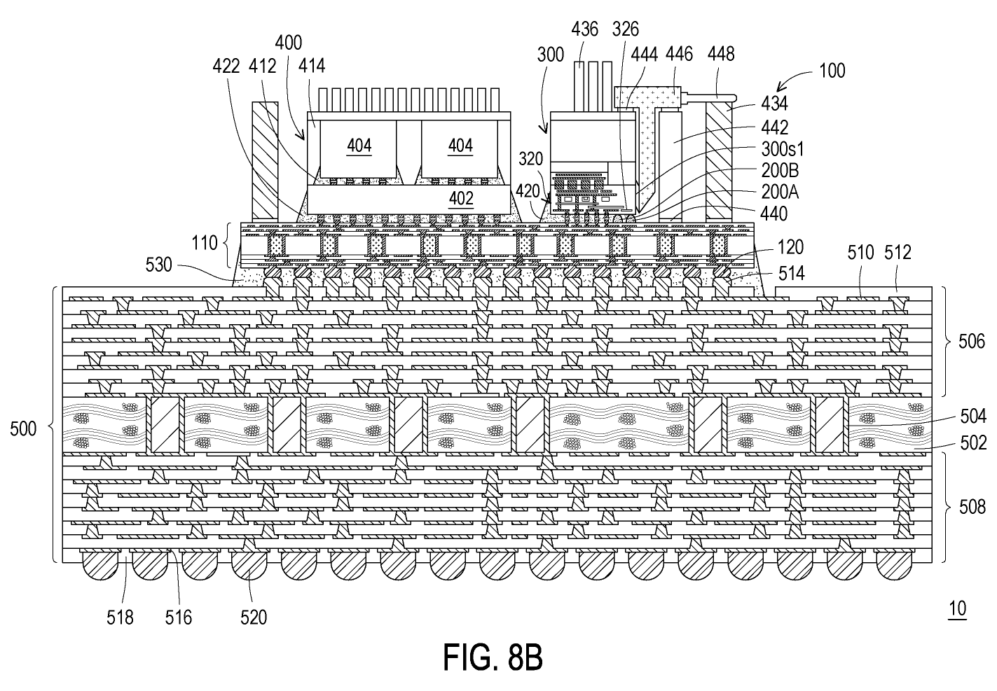

In some embodiments, as shown in FIG. 8A, there may be a plurality of dam structures 200A, 200B extending along the sidewall 300s1 of the PIC 320. For example, at least one dam structure is further disposed between the dam structure 200A and the conductive connector 116 immediately adjacent to the dam structure 200A. In such embodiments, the underfill 420 is further prevented from contacting and extending along the sidewall 300s1 of the PIC 320. The length of the dam structures 200A, 200B along the sidewall 300s1 of the PIC 320 may be different or substantially the same. For example, the length L1_{B} of the dam structures 200B is smaller than the length L1_{A} of the dam structures 200A. In some embodiments, the length L1_{A} of the dam structures 200A is substantially equal to the length L2 of the sidewall 300s1 of the PIC 320. However, the disclosure is not limited thereto. The dam structures 200A, 200B may have any suitable lengths. In some embodiments, as shown in FIG. 8B which may be a cross-sectional view along an extending line I-I’ of FIG. 8A, the underfill 420 surrounds the dam structure 200B. For example, the underfill 420 fills the gap between the joint structure (conductive connector 116/solder joints 352/conductive connector 350) and the dam structure 200B and the gap between the dam structures 200A and 200B. As shown in FIGS. 8A and 8B, the underfill 420 may contact an inner sidewall and end portions of the dam structure 200A. However, the disclosure is not limited thereto. In alternative embodiments, the underfill 420 further covers a portion of an outer sidewall of the dam structure 200A.

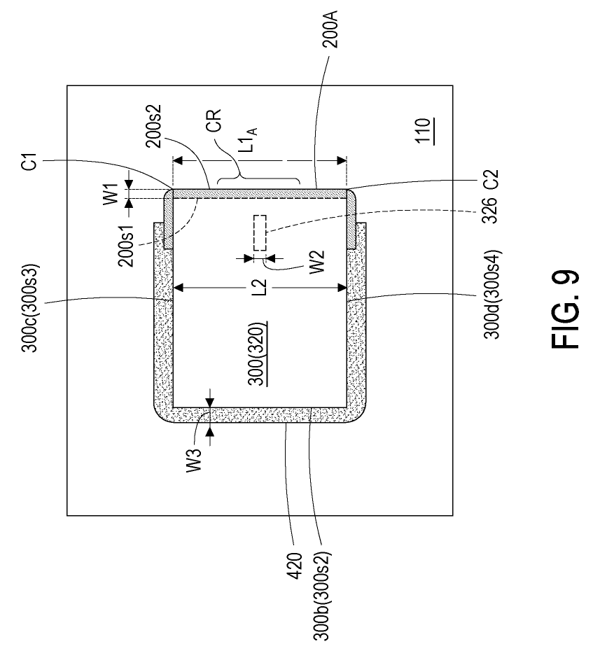

In some embodiments, as shown in FIG. 9, the dam structure 200 further extends along at least one of the sidewalls 300s3, 300s4 and thus surrounds at least one of the corners C1, C2. For example, the dam structure 200 extends along the sidewalls 300s1, 300s3, 300s4 and surrounds the corners C1, C2. In some embodiments, the underfill 420 may surround an end portion of the dam structure 200 along the sidewall 300s3, 300s4. However, the disclosure is not limited thereto. The underfill 420 may have a sidewall substantially flush with a sidewall of the dam structure 200.

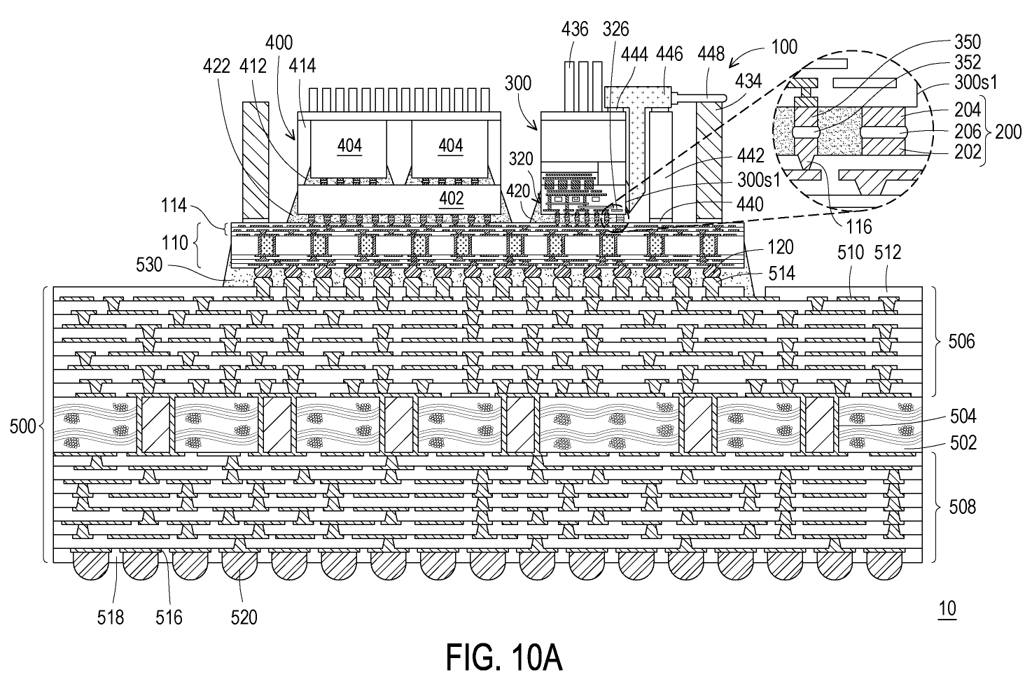

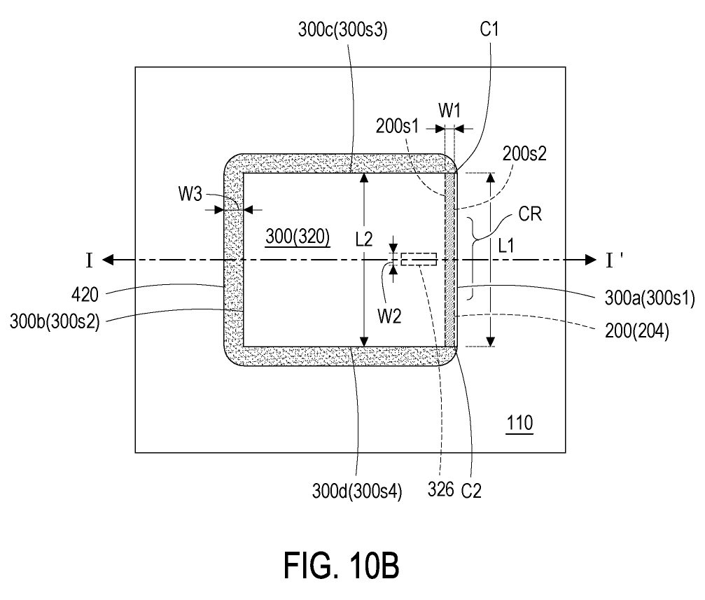

In the above embodiments, the interconnect substrate 110 and/or the dam structure 200 may have any other suitable configurations. For example, the interconnect substrate 110 in the above embodiments is an interposer such as a silicon interposer. As shown in FIG. 10A, the interconnect substrate 110 includes a semiconductor substrate 112, an interconnect structure 114 and conductive connectors 116, 120. The dam structure 200 in the above embodiments may include a stack structure. For example, ss shown in FIG. 10A, the dam structure 200a includes a first conductive layer 202, a second conductive layer 204 and a third conductive layer 206 sandwiched between the first and second conductive layers 202 and 204. A material of the third conductive layer 206 is different from a material of the first conductive layer 202 and the second conductive layer 204, and the material of the first conductive layer 202 and the second conductive layer 204 may be the same or different. In some embodiments in which the third conductive layer 206 is a solder layer, the dam structure 200 may have a similar structure to the joint structure of the package component 300 and the interconnect substrate 110 in a cross-sectional view while the dam structure 200 is elongated along the sidewall 300s1 as shown in FIG. 10B in a top view. The first conductive layer 202 may be formed simultaneously with the conductive connector 116 and have the same or similar material as the conductive connector 116, the second conductive layer 204 may be formed simultaneously with the conductive connector 350 and have the same or similar material as the conductive connector 350, and the third conductive layer 206 is formed after jointing the first conductive layer 202 and the second conductive layer 204 and have the same or similar material as the solder joint 352. In such embodiments, the first conductive layer 202 and the second conductive layer 204 are formed respectively on the package component 300 and the interconnect substrate 110. However, the disclosure is not limited thereto. The stack of the dam structure 200 may be formed on the interconnect substrate 110 or the PIC 320 before bonding he interconnect substrate 110 and the PIC 320.

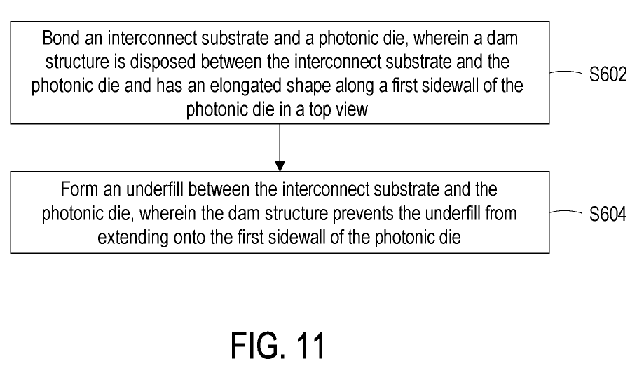

FIG. 11 illustrates a flowchart of a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S602, an interconnect substrate and a photonic die are bonded, wherein a dam structure is disposed between the interconnect substrate and the photonic die and has an elongated shape along a first sidewall of the photonic die in a top view. FIGS. 1D, 2C, 3C, 4C, 5A, 5B and 6-10B illustrate views corresponding to some embodiments of act S602.

At act S604, an underfill is formed between the interconnect substrate and the photonic die, wherein the dam structure prevents the underfill from extending onto the first sidewall of the photonic die. FIGS. 1E, 2D, 3B, 4B, 5A, 5B and 6-10B illustrate views corresponding to some embodiments of act S604.

According to some embodiments, a semiconductor device includes an interconnect substrate, a photonic die and an underfill. The photonic die is disposed over the interconnect substrate. The underfill is disposed between the interconnect substrate and the photonic die. The photonic die includes a first sidewall and a second sidewall opposite to the first sidewall, the first sidewall is covered by the underfill, and a central region of the second sidewall is free of the underfill.

According to some embodiments, a semiconductor device includes an interconnect substrate, a photonic die and a dam structure. The photonic die is disposed over the interconnect substrate. The dam structure is disposed between the interconnect substrate and the photonic die. The dam structure extends along a first sidewall of the photonic die and has a first length greater than 1/10 of a second length of the first sidewall.

According to some embodiments, a method of forming a semiconductor device includes following steps. An interconnect substrate and a photonic die are bonded, wherein a dam structure is disposed between the interconnect substrate and the photonic die and has an elongated shape along a first sidewall of the photonic die in a top view. An underfill is formed between the interconnect substrate and the photonic die, wherein the dam structure prevents the underfill from extending onto the first sidewall of the photonic die.

According to some embodiments, a semiconductor device includes an interconnect substrate, a photonic die and a dam structure. The dam structure is disposed between the interconnect substrate and the photonic die, and the dam structure has an elongated shape along a first sidewall of the photonic die in a top view.

According to some embodiments, a semiconductor device includes an interconnect substrate, a photonic die, an underfill and a dam structure. The underfill is disposed between the interconnect substrate and the photonic die. The dam structure is disposed between the interconnect substrate and the photonic die and extending along a first sidewall of the photonic die. A projection of the underfill on the interconnect substrate is separated from a projection of the first sidewall on the interconnect substrate.

According to some embodiments, a semiconductor device includes an interconnect substrate, a photonic die and an underfill. The photonic die is disposed over the interconnect substrate. The underfill is disposed between the interconnect substrate and the photonic die. The photonic die includes a first sidewall and a second sidewall opposite to the first sidewall, and the second sidewall of the photonic die overhangs a sidewall of the interconnect substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an interconnect substrate;
a photonic die; and
a dam structure, disposed between the interconnect substrate and the photonic die, wherein the dam structure has an elongated shape along a first sidewall of the photonic die in a top view.

2. The semiconductor device of claim 1, further comprising an underfill disposed between the interconnect substrate and the photonic die, wherein the underfill is disposed at a second sidewall opposite to the first sidewall of the photonic die.

3. The semiconductor device of claim 2, wherein a projection of the underfill on the first sidewall of the photonic die is separated from a projection of the dam structure on the first sidewall of the photonic die.

4. The semiconductor device of claim 2, wherein a projection of the underfill on the second sidewall of the photonic die is partially overlapped with a projection of the dam structure on the second sidewall of the photonic die.

5. The semiconductor device of claim 1, wherein the dam structure has a first length greater than 1/10 of a second length of the first sidewall.

6. The semiconductor device of claim 5, wherein the first length of the dam structure is substantially equal to the second length of the first sidewall.

7. A semiconductor device, comprising:
an interconnect substrate;
a photonic die;
an underfill, disposed between the interconnect substrate and the photonic die; and
a dam structure, disposed between the interconnect substrate and the photonic die and extending along a first sidewall of the photonic die,
wherein a projection of the underfill on the interconnect substrate is separated from a projection of the first sidewall on the interconnect substrate.

8. The semiconductor device of claim 7, wherein the dam structure interfaces with the first sidewall of the photonic die.

9. The semiconductor device of claim 7, wherein the underfill extends along a second sidewall opposite to the first sidewall, a third sidewall and a fourth sidewall of the photonic die.

10. The semiconductor device of claim 9, wherein the underfill further surrounds at least one of a corner between the third sidewall and the first sidewall and a corner between the third sidewall and the first sidewall.

11. The semiconductor device of claim 7, wherein a portion of the dam structure extends beyond the first sidewall.

12. The semiconductor device of claim 7, wherein a material of the dam structure comprises an UV glue, a thermal adhesive, a solder resist, a metal or a combination thereof.

13. The semiconductor device of claim 7, wherein the dam structure comprises a stack of a first conductive layer, a second metal layer and a solder layer sandwiched between the first and second conductive layers.

14. The semiconductor device of claim 7, wherein the dam structure has a shape of a partial sphere, a rectangle or a trapezoid in a cross-sectional view.

15. A semiconductor device, comprising:
an interconnect substrate;
a photonic die over the interconnect substrate; and
an underfill, disposed between the interconnect substrate and the photonic die,
wherein the photonic die comprises a first sidewall and a second sidewall opposite to the first sidewall, and the second sidewall of the photonic die overhangs a sidewall of the interconnect substrate.

16. The semiconductor device of claim 15, wherein the first sidewall is covered by the underfill, and a central region of the second sidewall is free of the underfill.

17. The semiconductor device of claim 16, wherein an entirety of the second sidewall is free of the underfill.

18. The semiconductor device of claim 16, wherein the photonic die comprises a photonic coupler aligned with the central portion of the second sidewall.

19. The semiconductor device of claim 15, further comprising a dam structure disposed between and overlapped with the photonic die and the interconnect substrate.

20. The semiconductor device of claim 19, wherein the photonic die comprises a plurality of conductive connectors bonded to the interconnect substrate, and the dam structure is disposed between the conductive connectors and the second sidewall of the photonic die.
